(19) United States
(12) Patent Application Publication
(10) Pub. No.: US 2026/0074005 A1
(43) Pub. Date: Mar. 12, 2026

(54) MEMORY DEVICE AND OPERATION METHOD THEREOF

(71) Applicant: Samsung Electronics Co., Ltd., Suwon-si (KR)

(72) Inventors: Byeongho Kim, Suwon-si (KR); SHINHAENG KANG, Suwon-si (KR); Suk Han Lee, Suwon-si (KR); KYOMIN SOHN, Suwon-si (KR)

(21) Appl. No.: 19/219,081

(22) Filed: May 27, 2025

(30) Foreign Application Priority Data
Sep. 9, 2024 (KR) 10-2024-0122693

(51) Int. Cl. G11C 29/44

(52) U.S. Cl. CPC G11C 29/44

(57) ABSTRACT

A memory device configured to receive a processing command from an external host device may be provided. The memory device may comprise an in-memory processor configured to perform an in-memory processing operation in response to the processing command, and an error report circuit configured to provide, in response to the processing command, one or more error records indicating errors detected during the in-memory processing operation, to the external host device in response to the processing command.

### CROSS-REFERENCE TO RELATED APPLICATION

This application claims priority to and the benefit of Korean Patent Application No. 10-2024-0122693 filed at the Korean Intellectual Property Office on Sep. 9, 2024, the entire contents of which are herein incorporated by reference.

### BACKGROUND OF THE INVENTION

### (a) Field of the Invention

The present disclosure relates to a semiconductor memory device. More specifically, the present disclosure relates to a memory device performing an in-memory processing operation and an operation method thereof.

### (b) Description of the Related Art

An operation speed of a memory system including a memory device and a host device is bottlenecked by a communication speed between the memory device and the host device. Accordingly, various technologies for solving a bottleneck phenomenon caused by the communication speed are being researched. For example, a processing-in-memory (PIM) technology in which the memory device performs an in-memory processing operation has been recently researched.

The memory device may include an in-memory processor. The in-memory processor may perform various calculation operations in response to a request from the host device to generate a calculation result. The in-memory processor may store the calculation result in a register within the in-memory processor, instead of returning the calculation result directly to the host device in response to the request. Therefore, the host device may not identify whether the calculation result has an error, and thus may continue a subsequent operation even when the calculation result has the error.

### SUMMARY

The present disclosure is intended to solve the above-described technical problem. More specifically, an object of the present disclosure is to provide a memory device configured to feedback an error that occurs during an in-memory processing operation and an operation method thereof.

According to an aspect of the present disclosure, a memory device includes an in-memory processor configured to receive a processing command from an external host device and perform an in-memory processing operation in response to the processing command, and an error report circuit configured to provide, in response to the processing command, one or more error records indicating errors detected during the in-memory processing operation, to the external host device.

According to an aspect of the present disclosure, a memory device includes a plurality of data pins, a report level register configured to store a report level, an in-memory processor configured to perform an in-memory processing operation in response to a processing command and generate one or more error records indicating information of an error occurring during the in-memory processing operation, and an error report circuit configured to provide, based on the report level, the one or more error records of the in-memory processing operation to the plurality of data pins.

According to an aspect of the present disclosure, an operation method of a memory device including an in-memory processor includes receiving a processing command, attempting in-memory processing corresponding to the processing command, and outputting one of default data and an error record for the in-memory processing, based on whether an error occurs during the in-memory processing. The default data represent that the in-memory processing has no error.

### BRIEF DESCRIPTION OF THE DRAWINGS

FIG. 1 is a block diagram showing a memory system according to an embodiment of the present disclosure.

FIG. 2 is a block diagram showing a memory device of FIG. 1 in more detail.

FIG. 3 is a drawing showing a report level register of FIG. 2 implemented according to an embodiment.

FIG. 4 is a block diagram showing an in-memory processor of FIG. 2 in more detail.

FIG. 5 is a timing diagram showing an operation method the memory device in a non-report mode.

FIG. 6 is a timing diagram showing an operation method the memory device in an error report mode.

FIG. 7 is a block diagram showing a configuration and an operation of an error detection circuit of FIG. 4 in more detail.

FIG. 8 shows a type of an error record that may be stored in an error record register of FIG. 7.

FIG. 9 is a drawing showing an operation of an error report circuit operating in the non-report mode.

FIG. 10 is a drawing showing an operation of the error report circuit operating in the error report mode.

FIG. 11 is a flowchart showing the operation of the memory device operating in the error report mode.

FIG. 12 is a drawing showing the report level register of FIG. 2 implemented according to an embodiment.

FIG. 13 shows an importance level of each error record that may be stored in the error record register of FIG. 7.

FIG. 14 is a drawing showing an operation of the error report circuit operating in an important error report mode.

FIG. 15 is a block diagram showing an error record register of FIG. 14 implemented according to an embodiment.

FIG. 16 is a block diagram showing a memory system according to an embodiment.

### DETAILED DESCRIPTION OF THE EMBODIMENTS

Below, embodiments of the present disclosure will be described clearly and in detail to such an extent that a person of an ordinary skill in the technical field of the present disclosure may easily perform the present disclosure. Details such as detailed configurations and structures are provided simply to facilitate an overall understanding of the embodiments of the present disclosure. Therefore, modifications of the embodiments described in the present disclosure may be performed by a person of an ordinary skill in the art without departing from the technical spirit and scope of the present disclosure. Moreover, descriptions of well-known functions and structures are omitted for clarity and brevity. Configurations in the drawings or a detailed description of the present disclosure may be connected to an element other than that shown in the drawings or described in the detailed description. Terms used in the present disclosure are defined considering functions of the present disclosure, and are not limited to specific functions. The definition of the terms may be determined based on details described in the detailed description.

Elements described with reference to terms used in the detailed description may be implemented in the form of software, hardware, or a combination thereof. For example, the software may be a machine code, firmware, an embedded code, and application software. For example, the hardware may include an electrical circuit, an electronic circuit, a processor, a computer, integrated circuit cores, a pressure sensor, an inertial sensor, a microelectromechanical system (MEMS), a passive element, or a combination thereof.

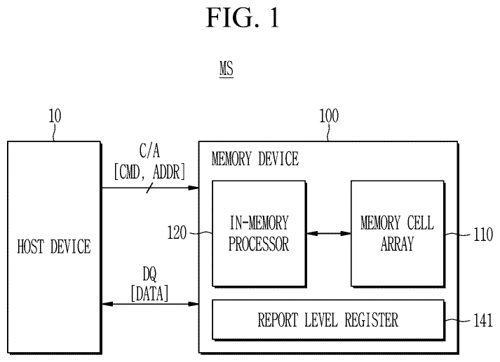

FIG. 1 is a block diagram showing a memory system according to an embodiment of the present disclosure. Referring to FIG. 1, the memory system MS may include a host device 10 and a memory device 100. The memory device 100 may include a memory cell array 110, an in-memory processor 120 (i.e., an in-memory processor circuit), and a report level register 141.

In an embodiment, the memory system MS may be included in various types of electronic devices such as a smartphone, a laptop, a personal computer, and a tablet PC.

In an embodiment, the host device 10 may include one of various types of processors such as a central processing unit (CPU) and a graphics processing unit (GPU).

Hereinafter, it is assumed that the memory device 100 is a dynamic random access memory (DRAM) device. The host device 10 and the memory device 100 may communicate with each other based on a low power double data rate (LPDDR) interface. However, the scope of the present disclosure is not limited thereto. For example, the host device 10 and the memory device 100 may communicate with each other based on a double data rate (DDR) interface. In an embodiment, the host device 10 and the memory device 100 may operate according a memory interface standard adopted by Joint Electron Device Engineering Council (JEDEC), which develops open standards between a host device and a memory device communicate with the host device.

The host device 10 may control an operation of the memory device 100 by transmitting a command CMD and/or an address ADDR to the memory device 100. For example, the host device 10 may provide the command CMD and the address ADDR to the memory device 100 based on a plurality of command/address signals C/A.

The memory device 100 may operate in response to a control of the host device 10. For example, in response to the command CMD and/or the address ADDR, the memory device 100 may store data DATA in the memory cell array 110 by latching data signals DQ, or may provide the data DATA stored in the memory cell array 110 to the host device 10 in the data signals DQ.

In an embodiment, the memory device 100 may transmit and receive the data signals DQ for a read operation or a write operation via a plurality of data pins. In an embodiment, the data pins may be used for providing an error record to the host device 10. The error record may indicate an error detected while an in-memory processing operation is performed.

The memory device 100 may perform various calculation operations in response to a control of the host device 10. For example, the in-memory processor 120 may perform various calculation operations (i.e., in-memory processing operations) based on a processing command (hereinafter referred to as “PROC”) provided from the host device 10. The in-memory processor 120 (or processing-in-memory, PIM) is a computing architecture where data processing occurs directly within the memory device 100 rather than transferring data back and forth between the host device 10 and the memory device 100. With the in-memory processor 120 in the memory device 100, latency, power consumption, and data movement overhead in the memory system may be reduced.

In an embodiment, the in-memory processor 120 may perform a calculation operation (i.e., a computation or mathematical calculation) based on one or more operands. For example, the in-memory processor 120 may perform various calculations such as summation, multiplication, and multiplication and accumulation (MAC). In an embodiment, the one or more operands may be data represented in a matrix form. With the in-memory processor 120, without receiving the one or more operands from the memory device 100, the host device 10 may receive a calculation result generated based on the one or more operands from the memory device. Therefore, according to the embodiment of the present disclosure, a bottleneck phenomenon in an operation of the memory system MS caused by communication between the host device 10 and the memory device 100 may be minimized.

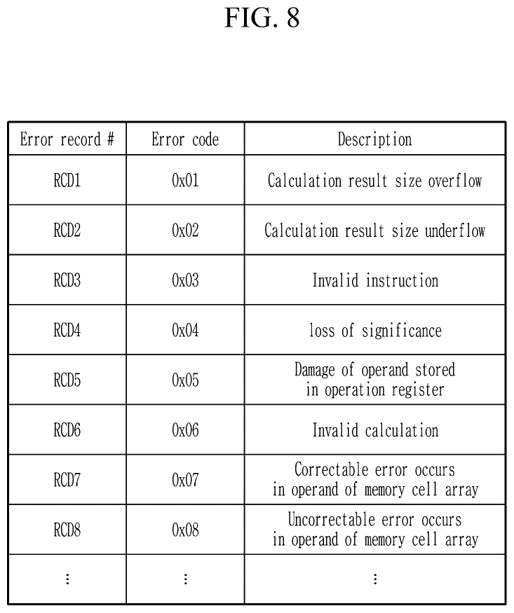

The in-memory processor 120 may detect various types of errors occurring while performing the in-memory processing operation. For example, the in-memory processor 120 may detect the error causing failure of the calculation result. However, the scope of the present disclosure is not limited to the types of errors detected by the in-memory processor 120. Examples of the various types of errors detected by the in-memory processor 120 will be described in more detail below with reference to FIG. 8.

The report level register 141 may determine an operation mode of the memory device 100. For example, the report level register 141 may store a report level (hereinafter referred to as “RPL”) indicating one of an error report mode (hereinafter referred to as “MODE_ER”) and an error non-report mode (hereinafter referred to as “MODE_NR”).

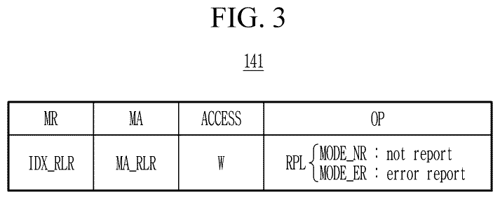

In an embodiment, the report level register 141 may be implemented as a mode register MR. In an embodiment, the mode register MR may correspond to a mode register of a DRAM device which stores information used to configure various operational parameters of the DRAM device. The mode register MR may control how the memory device 110 functions, optimizing it for different system requirements such as speed, latency, and power consumption. In some embodiments, the mode register MR may further serve as the report level register 141. In an embodiment, the report level RPL may be written in response to a mode register write (MRW) command. In an embodiment, the MRW command may be specified by LPDDR interface. An embodiment in which the report level register 141 is implemented as the mode register will be described in more detail below with reference to FIG. 3.

If the report level RPL indicates the error report mode MODE_ER, the memory device 100 may operate in the error report mode MODE_ER. The in-memory processor 120 may report an error detected during the in-memory processing operation to the host device 10. For example, the in-memory processor 120 may provide an error record (hereinafter referred to as “RCD”) indicating the detected error to the host device 10 via the data signals DQ (i.e., via the data pins of the memory device 100). In a read operation or a write operation, data stored in a memory cell array or data to be written to the memory cell array is communicated through the data pins, and in an in-memory processing operation, the error record of the in-memory processing operation is provided to the host device 10 via the data pins.

In an embodiment, the in-memory processor 120 may report an error detected during the in-memory processing operation performed in response to the processing command PROC to the host device 10, as an operation sequence corresponding to the processing command PROC. For example, after a certain time length has elapsed from a time point when the processing command PROC was received, the in-memory processor 120 may report an error to the host device 10 which occurs during the in-memory processing operation corresponding to the processing command PROC. Accordingly, the host device 10 may immediately recognize that the error has occurred during the in-memory processing operation for the processing command PROC. Upon the recognition of the error, the host device 10 may stop a subsequent calculation for the in-memory processing calculation in which the error has occurred, so that an unnecessary calculation is minimized and an operation efficiency of the memory system MS is improved.

If the report level RPL indicates the error non-report mode MODE_NR, the memory device 100 may operate in the error non-report mode MODE_NR. For example, the in-memory processor 120, detecting an error while the in-memory processing operation is performed, may store an error record RCD for the error within the in-memory processor 120 instead of immediately reporting the error to the host device 10. The error record RCD may indicate information of an error occurring during the in-memory processing operation performed in response to the processing command PROC.

In an embodiment, the memory device 100 may provide the error record RCD stored in the in-memory processor 120 to the host device 10 in response to an error record read command other than the processing command PROC. However, the scope of the present disclosure is not limited thereto.

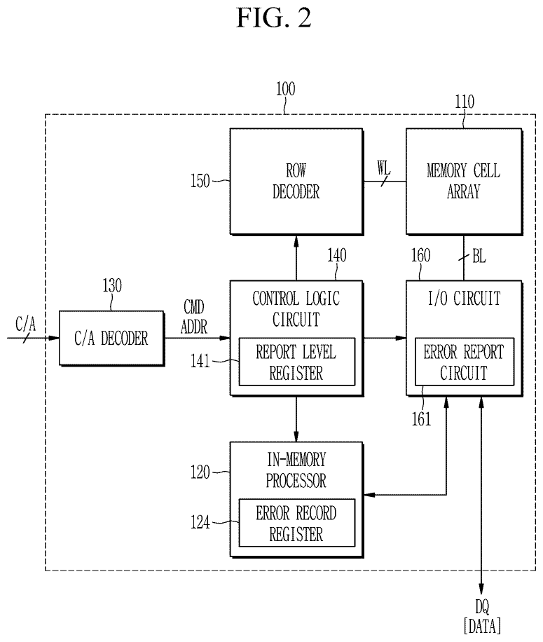

FIG. 2 is a block diagram showing a memory device of FIG. 1 in more detail. Referring to FIG. 2, the memory device 100 may include the memory cell array 110, the in-memory processor 120, a command/address decoder 130, a control logic circuit 140, a row decoder 150, and an input/output circuit 160.

The memory cell array 110 may include a plurality of memory cells disposed in a row direction and a column direction. The plurality of memory cells may be connected to a plurality of word lines WL extending in the row direction and a plurality of bit lines BL extending in the column direction.

The command/address decoder 130 may receive the command/address signals C/A provided from the host device 10. The command/address decoder 130 may decode the plurality of command/address signals C/A into the command CMD and the address ADDR.

The control logic circuit 140 may receive the command CMD and the address ADDR from the command/address decoder 130. The control logic circuit 140 may control an overall operation of the memory device 100 based on the command CMD and the address ADDR. For example, the control logic circuit 140 may control operations of the in-memory processor 120, the row decoder 150, and the input/output circuit 160.

The row decoder 150 may control the plurality of word lines WL based on a control of the control logic circuit 140. For example, the row decoder 150 may activate one of the plurality of word lines WL in response to the control of the control logic circuit 140.

The input/output circuit 160 may receive data DATA indicated by the data signals DQ from the host device 10, or may transmit data DATA to the host device 10 by the data signals DQ.

The input/output circuit 160 may be connected to the memory cell array 110 through the plurality of bit lines BL. The input/output circuit 160 may control the plurality of bit lines BL to read data DATA stored in the memory cell array 110 or store data DATA in the memory cell array 110.

The control logic circuit 140 may control an operation of the in-memory processor 120 based on the processing command PROC. The in-memory processor 120 may perform the in-memory processing operation in response to a control of the control logic circuit 140. For example, the in-memory processor 120 may generate a calculation result by performing various types of calculation operations, and then may store the generated result within the in-memory processor 120.

The in-memory processor 120 may include an error record register 124. The in-memory processor 120 may store the error record RCD in the error record register 124. The error record RCD may indicate information of an error occurring during the in-memory processing operation, in the error record register 124.

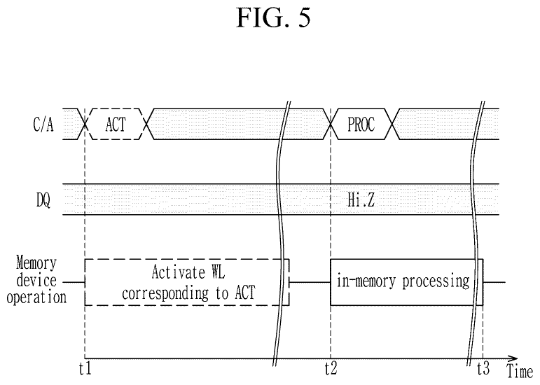

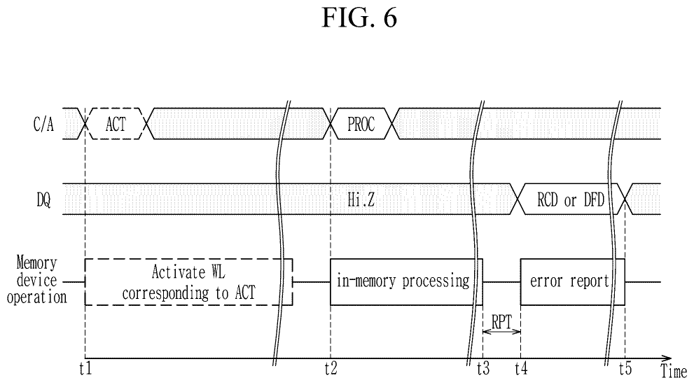

The control logic circuit 140 may include the report level register 141. The report level register 141 may store the report level RPL. The report level RPL may determine an operation sequence of the memory device 100 in response to the processing command PROC. For example, a method in which the control logic circuit 140 controls each component of the memory device 100 in response to the processing command PROC may vary according to the report level RPL stored in the report level register 141. A detailed method in which the operation sequence of the memory device 100 in response to the processing command PROC varies according to the report level RPL will be described in more detail with reference to FIG. 5 and FIG. 6.

The input/output circuit 160 may include an error report circuit 161. The error report circuit 161 may operate in one of the error report mode MODE_ER and the error non-report mode MODE_NR based on the report level stored in the report level register 141.

If the error report circuit 161 operates in the error report mode MODE_ER, the error report circuit 161 may output the error record RCD stored in the error record register 124 in a form of the data signals DQ (i.e., via the data pins of the memory device 100) within an operation sequence for one processing command PROC. For example, the error report circuit 161 may output the error record RCD, which is corresponding to the processing command PROC and provided from the error record register 124, through the data signals DQ within the operation sequence for the processing command PROC.

In an embodiment, if the error report circuit 161 operates in the error report mode MODE_ER and there is no error record RCD stored in the error record register 124, the error report circuit 161 may output default data through the data signal DQ. The default data may refer to data such as 0x0000 which is represented by the data signals DQ when all data signals DQ are logic low. However, the scope of the present disclosure is not limited to a specific implementation method of the default data.

If the error report circuit 161 operates in the error non-report mode MODE_NR, the error report circuit 161 may not output the error record RCD stored in the error record register 124 through the data signals DQ. For example, the error report circuit 161 may keep the data pins outputting the data signal DQ with Hi-Z state within the operation sequence for the processing command PROC. For example, if the error report circuit 161 operates in the error non-report mode MODE_NR, the calculation result or the error record generated by attempting to perform the in-memory processing operation may be stored in the in-memory processor 120, and may not be provided to the host device 10.

In an embodiment, if the error report circuit 161 operates in the error non-report mode MODE_NR, the error report circuit 161 may output the error record RCD stored in the error record register 124 in a form of the data signals DQ in response to the error record read command. For example, if the error report circuit 161 operates in the error non-report mode MODE_NR, the memory device 100 may not provide the error record RCD to the host device 10 until a separate error record read command other than the processing command PROC is received.

In an embodiment, the error report circuit 161 is shown below as a configuration included in the input/output circuit 160, but the scope of the present disclosure is not limited thereto. For example, the error report circuit 161 may be implemented as firmware or software controlling an operation of the input/output circuit 160, or a function of the error report circuit 161 may be performed by the input/output circuit 160. For example, the scope of the present disclosure is not limited to a specific implementation method of the error report circuit 161.

FIG. 3 is a drawing showing the report level register of FIG. 2 implemented according to an embodiment. Referring to FIGS. 1 to 3, the report level register 141 may be implemented as a mode register. Hereinafter, the embodiment in which the report level register 141 is implemented as the mode register will be representatively described. However, the scope of the present disclosure is not limited thereto, and the report level register 141 may be implemented as any type of a register that may be managed according to a request of the host device 10.

A mode register number of the report level register 141 may be determined as a report level register index IDX_RLR. A mode address of the report level register 141 may be determined as a report level register mode address MA_RLR. An access mode of the report level register 141 may be set as a write mode W. In an embodiment, the report level register index IDX_RLR may have a value corresponding to the report level register mode address MA_RLR.

An operation code OP of the report level register 141 may indicate the report level RPL. The report level RPL may indicate one of the non-report mode MODE_NR and the error report mode MODE_ER. For example, if the operation code OP of the report level register 141 is “0x00”, the report level register 141 may indicate the non-report mode MODE_NR, and if the operation code OP of the report level register 141 is “0x01”, the report level register 141 may indicate the error report mode MODE_ER. However, the scope of the present disclosure is not limited to a value of the operation code OP of the report level register 141.

In an embodiment, the report level register 141 may be written in response to the mode register write (MRW) command, which is defined in the LPDDR interface, for example. For example, the host device 10 may change the report level RPL by issuing the mode register write command.

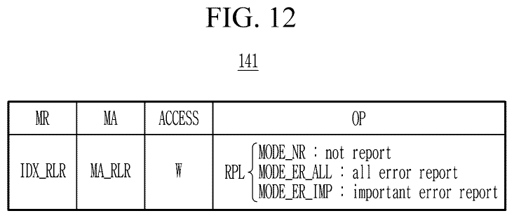

In an embodiment, the report level register 141 may indicate a plurality of different error report modes MODE_NR. For example, the report level register 141 may represent a plurality of differently defined error report modes MODE_NR such as a mode that reports all errors detected during the in-memory processing operation in response to one processing command PROC, or a mode that reports only important errors. The different error report modes MODE_NR may correspond to values of different operation codes OP. The report level register which is configured to indicate one of the plurality of error report modes MODE_NR will be described in more detail below with reference to FIG. 12.

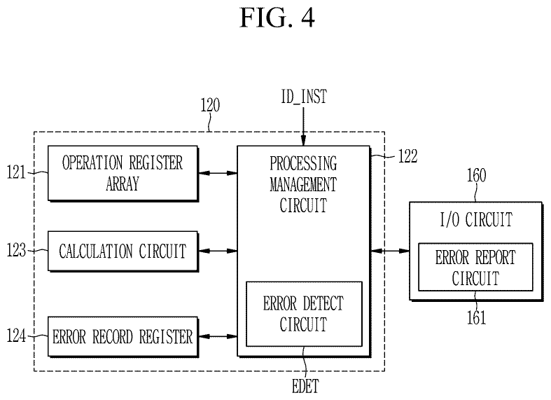

FIG. 4 is a block diagram showing the in-memory processor of FIG. 2 in more detail. Referring to FIGS. 1 to 4, the in-memory processor 120 may include an operation register array 121, a processing management circuit 122, a calculation circuit 123, and the error record register 124.

The operation register array 121 may include a plurality of operation registers. The plurality of operation registers may store various types of data required for the in-memory processing operation. For example, the plurality of operation registers may store different types of instructions each representing the in-memory processing operation, may store operands used in the in-memory processing operation, and may store a calculation result generated by the in-memory processing operation.

Each of the instructions stored in the operation register array 121 may define an in-memory processing operation to be performed by the in-memory processor 120. For example, each of the instructions stored in the operation register array 121 may correspond to different combinations of ‘a type of calculation to be performed by the in-memory processor 120, locations where the operands stored, and a location where the calculation result is to be stored’.

The processing management circuit 122 may control an overall operation of the in-memory processor 120 in response to a control of the control logic circuit 140. For example, the processing management circuit 122 may communicate with the operation register array 121, the calculation circuit 123, the error record register 124, and the input/output circuit 160 in response to the control of the control logic circuit 140.

For a more detailed example, the control logic circuit 140 may provide an instruction identifier ID_INST included in the processing command PROC to the processing management circuit 122. The processing management circuit 122 may control an overall operation of the in-memory processor 120 to perform the in-memory processing operation indicated by an instruction corresponding to the identifier ID_INST from among the instructions stored in the operation register array 121.

The calculation circuit 123 may perform a calculation operation in response to a control of the processing management circuit 122. For example, the processing management circuit 122 may provide an operand of the memory cell array 110 provided via the input/output circuit 160 to the calculation circuit 123, and/or may provide an operand stored in the operation register array 121 to the calculation circuit 123. The calculation circuit 123 may generate a calculation result based on the one or more received operands.

In an embodiment, the calculation circuit 123 may generate a calculation result based on a first operand stored in the operation register array 121 and a second operand provided from the memory cell array 110. However, the scope of the present disclosure is not limited thereto, and the calculation circuit 123 may generate a calculation result based on only one or more operands stored in the operation register array 121, or may generate a calculation result based on only one or more operands stored in the memory cell array 110.

The calculation circuit 123 may store the generated calculation result in the operation register array 121. For example, the processing management circuit 122 may store the calculation result generated from the calculation circuit 123 in the operation register array 121.

The memory device 100 may provide the calculation result stored in the operation register array 121 to the host device 10, in response to a calculation result read command issued from the host device 10. For example, the processing management circuit 122 may provide the calculation result stored in the operation register array 121 to the host device 10 through the input/output circuit 160. For example, the memory device 100 may store the calculation result in the operation register array 121 until a separate calculation result read command is received, instead of immediately providing a calculation result generated in response to the processing command PROC to the host device 10. In this case, because data transmission between the memory device 100 and the host device 10 is minimized when a subsequent calculation based on the calculation result is performed, an operation speed of the memory device 100 may be improved. Only when the host device 10 performs a subsequent operation (including a subsequent calculation) based on the calculation result of the in-memory processor 120, the calculation result is transmitted to the host device 10, thereby reducing communication between the host device 10 and the memory device 100. However, if the memory device 100 does not immediately provide the calculation result generated in response to the processing command PROC to the host device 10, it may be difficult for the host device 10 to recognize an error occurring during the in-memory processing operation of the memory device 100 in response to the processing command PROC. Hereinafter, a method allowing the host device 10 to more quickly recognize an error occurring during the in-memory processing operation will be described.

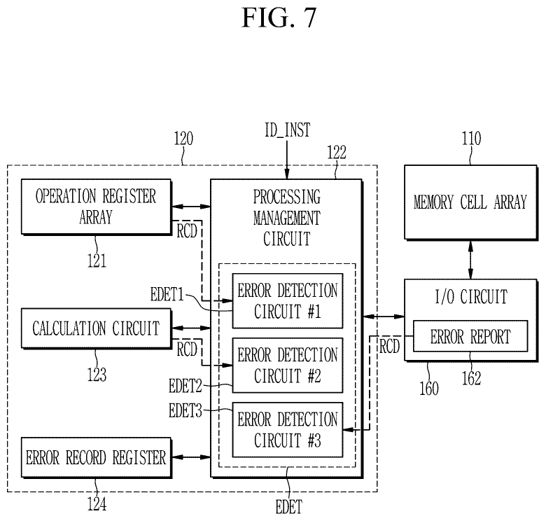

The processing management circuit 122 may include an error detection circuit EDET. The error detection circuit EDET may detect an error occurring during the in-memory processing operation. The error detection circuit EDET may detect various types of errors occurring while the in-memory processor 120 attempts to perform the in-memory processing operation corresponding to the instruction identifier ID_INST. A more detailed configuration and operation of the error detection circuit EDET will be described later with reference to FIG. 7.

The error detection circuit EDET may generate the error record RCD corresponding to the detected error. The error detection circuit EDET may store the generated error record RCD in the error record register 124.

In this way, the error record register 124 may store one or more error records RCD. The error report circuit 161 may provide one or more error records RCD stored in the error record register 124 to the host device 10 via the data signals DQ (i.e., via the data pins). A time point at which the error report circuit 161 provides the one or more error records to the host device 10 may vary according to the report level RPL.

FIG. 5 is a timing diagram showing an operation method of the memory device in the non-report mode. Hereinafter, an operation of the memory device 100 when the report RPL represents the non-report mode MODE_NR will be described with reference to FIGS. 1 to 5.

An embodiment in which the memory device 100 generates a calculation result based on a first operand stored in the operation register array 121 and a second operand stored in the memory cell array 110 will be representatively described below.

The host device 10 may provide an activation command ACT to the memory device 100 at a first time point t1. A command sequence of the activation command ACT may include one row address. The memory device 100 may activate the word line WL corresponding to the row address in response to the activation command ACT. For example, the control logic circuit 140 may control the row decoder 150 to activate the word line corresponding to the row address indicated by the activation command ACT. Data stored in memory cells connected to the activated word line WL may be stored in the input/output circuit 160 (e.g., a sense amplification circuit). In an embodiment, the input/output circuit 160 may include a sense amplification circuit operating in response to the activation command ACT.

The host device 10 may provide the processing command PROC to the memory device 100 at a second time point t2. A command sequence of the processing command PROC may include the instruction identifier ID_INST and a column address.

During a time period between the second time point t2 and a third time point t3, the memory device 100 may perform the in-memory processing operation in response to the processing command PROC. For example, the in-memory processor 120 may identify the first operand corresponding to an instruction indicated by the instruction identifier ID_INST. The in-memory processor 120 may receive the second operand corresponding to the column address indicated by the processing command PROC from among data stored in the input/output circuit 160 (e.g., the sense amplification circuit). The in-memory processor 120 may generate a calculation result based on the first operand and the second operand. The in-memory processor 120 may store the calculation result in the operation register array 121.

Between the second time point t2 and the third time point t3, the in-memory processor 120 may store the error record RCD indicating the error occurring during the in-memory processing operation in the error record register 124. For example, the error detection circuit EDET may store the error record RCD in the error record register 124. Therefore, if an error is detected while the in-memory processing operation is attempted, one or more error records RCD may be stored in the error record register 124 at the third time point t3. If the in-memory processing operation is successfully performed, the error record RCD may not be stored in the error record register 124 at the third time point t3.

If the report level RPL indicates the non-report mode MODE_NR, the memory device 100 may end an operation sequence of the processing command PROC at the third time point t3 at which the in-memory processing operation is completed. For example, the memory device 100 may not perform an additional operation on the processing command PROC after the third time point t3.

If the report level RPL indicates the non-report mode MODE_NR, the memory device 100 may not provide the error record RCD to the host device 10 as the operation sequence of the processing command PROC. For example, the error report circuit 161 may not provide the one or more error records RCD stored in the error record register 124 to the host device 10 until a separate error report command (not shown) is received after the third time point t3. In an embodiment, the separate error report command may be received from the host device 10.

For example, if the report level RPL indicates the non-report mode MODE_NR, the memory device 100 may not transmit data to the host device 10 in response to the processing command PROC. For example, even if the processing command PROC is received, the memory device 100 may not provide the data signal DQ indicating the calculation result or the error record RCD to the host device 10. Therefore, if the report level RPL indicates the non-report mode MODE_NR, the plurality of data pins transmitting the data signals DQ may be kept in an inactive state (e.g., a Hi-Z state) until the operation sequence for the processing command PROC is terminated.

In an embodiment, the embodiment in which the memory device 100 generates the calculation result based on the first operand stored in the operation register array 121 and the second operand stored in the memory cell array 110 has been representatively described in FIG. 5. However, the scope of the present disclosure is not limited thereto, and the memory device 100 may operate based on only one or more operands stored in the memory cell array 110, or may operate based on only one or more operands stored in the operation register array 121.

In an embodiment, the memory device 100 may perform the in-memory processing operation based on only one or more operands stored in the operation register array 121. For example, the memory device 100 may perform the in-memory processing operation regardless of data stored in the memory cell array 110. In an embodiment, the host device 10 may not issue the activation command ACT prior to the processing command PROC. The dotted box corresponding to an operation initiated by the activation command ACT may be omitted.

FIG. 6 is a timing diagram showing an operation method of the memory device in the error report mode. Hereinafter, an operation of the memory device 100 when the report level RPL indicates the error report mode MODE_ER will be described with reference to FIGS. 1 to 6. Hereinafter, a difference between the operation of the memory device 100 when the report level RPL indicates the error report mode MODE_ER, and the operation of the memory device 100 when the report RPL represents the error non-report mode MODE_NR described above with reference to FIG. 5 will be mainly described.

Similar to the one described above with reference to FIG. 5, the memory device 100 may receive the activation command ACT at a first time point t1, and may receive the processing command PROC at a second time point t2. The memory device 100 may perform the in-memory processing operation in response to the processing command PROC during a time period between the second time point t2 and a third time point t3.

If an error is detected between the second time point t2 and the third time point t3, one or more error records RCD may be stored in the error record register 124 at the third time point t3. If the error is not detected during a time period between the second time point t2 and the third time point t3 (i.e., if the in-memory processing operation is successfully performed), the error record RCD may not be stored in the error record register 124 at the third time point t3.

If the report level RPL indicates the error report mode MODE_ER, the memory device 100 may perform an error report operation after the third time point t3 when the in-memory processing operation is completed. For example, unlike what previously described with reference to FIG. 5, the memory device 100 may further perform the error report operation as an operation sequence for the processing command PROC after the third time point t3. For example, the error report circuit 161 may activate the plurality of data pins at a fourth time point t4 after a report preparation time RPT has elapsed from the third time point t3. In a time period between the fourth time point t4 and a fifth time point t5, the error report circuit 161 may provide the data signals DQ indicating the one or more error records RCD or default data DFD to the host device 10 through the plurality of data pins.

The report preparation time RPT may refer to a time required for the error report circuit 161 to receive the one or more error records RCD from the error record register 124 and to prepare the transmission of the one or more error records RCD through the plurality of data pins. For example, during the report preparation time RPT, the input/output circuit 160 may receive the one or more error records RCD from the error record register 124, and may allocate the one or more error records RCD on the plurality of data pins so that the one or more error records RCD may be sequentially transmitted to the host device 10 in response to a rising edge and/or a falling edge of a write clock (WCK). In an embodiment, the WCK may be defined in the LPDDR interface.

In an embodiment, a length of the report preparation time RPT may be predetermined. For example, the length of the report preparation time RPT may be adjusted based on the mode register write (MRW) command. However, the scope of the present disclosure is not limited thereto.

In an embodiment, if the one or more error records are stored in the error record register 124 at the third time point t3, the error report circuit 161 may provide at least some of the one or more error records RCD stored in the error record register 124 to the host device 10 via the data signals DQ between the fourth time point t4 and the fifth time point t5.

In an embodiment, if the error record is not stored in the error record register 124 at the third time point t3 (more specifically, if the error record RCD corresponding to the processing command PROC of the second time point t2 is not stored in the error record register 124), the error report circuit 161 may provide the default data DFD to the host device 10 through the data signals DQ between the fourth time point t4 and the fifth time point t5.

In an embodiment, the default data DFD may represent data transmitted through the data signals DQ when all data signals DQ represent logic low. However, the scope of the present disclosure is not limited thereto.

At the fifth time point t5 when the one or more error records RCD or the default data DFD are provided to the host device 10, the memory device 100 may end the operation sequence for the processing command PROC. In an embodiment, the error record RCD for the processing command PROC may be immediately provided to the host device 10 as the operation sequence for the processing command PROC. Therefore, if the memory device 100 operates based on the error report mode MODE_ER, the host device 10 may control the memory device 100 more efficiently, and an operation efficiency of the memory system MS may be improved.

A total length of the operation sequence of the memory device 100 for the processing command PROC when the report level RPL indicates the error report mode MODE_ER may be longer than a total length of the operation sequence of the memory device 100 for the processing command PROC when the report level RPL indicates the error non-report mode MODE_NR. Therefore, if the memory device 100 operates based on the error non-report mode MODE_NR, an operation speed of the memory system MS may be improved.

In an embodiment, the host device 10 may determine an operation mode of the memory device 100 according to a type of calculation to be instructed to the memory device 100. For example, if an error occurrence probability of the in-memory processing operation is expected to be high, the host device 10 may set the report level register 141 to indicate the error report mode MODE_ER. If the error occurrence probability of the in-memory processing operation is expected to be low, the host device 10 may set the report level register 141 to indicate the error non-report mode MODE_NR. However, the scope of the present disclosure is not limited thereto.

FIG. 7 is a block diagram showing a configuration and an operation of the error detection circuit of FIG. 4 in more detail. Referring to FIGS. 1 to 7, the error detection circuit EDET may include a first error detection circuit EDET1, a second error detection circuit EDET2, and a third error detection circuit EDET3. However, the scope of the present disclosure is not limited thereto, and the error detection circuit EDET may include one or two of the first error detection circuit EDET1, the second error detection circuit EDET2, and the third error detection circuit EDET3. In an embodiment, the error detection circuit may include four or more error detection circuits.

The first error detection circuit EDET1 may collect the error record RCD from the operation register array 121. For example, the first error detection circuit EDET1 may detect an error occurred by a configuration or an operation of the operation register array 121. In an embodiment, the first error detection circuit EDET1 may detect various types of errors such as size overflow of the calculation result, size underflow of the calculation result, damage (e.g., defect of integrity) of the operand stored in the operation register array 121, and undefined instruction execution.

In an embodiment, the first error detection circuit EDET1 may detect the size overflow of the calculation result and the size underflow of the calculation result by comparing a size of the operation register corresponding to a position where the calculation result is to be stored with the calculation result.

In an embodiment, the first error detection circuit EDET1 may detect the damage of the operand stored in the operation register array 121 based on various data damage detection algorithms such as a parity check and a cyclic redundancy check (CRC).

In an embodiment, the first error detection circuit EDET1 may detect the undefined instruction execution based on whether an instruction corresponding to the instruction identifier ID_INST is stored in the operation register array 121.

The second error detection circuit EDET2 may collect the error record RCD from the calculation circuit 121. For example, the second error detection circuit EDET2 may detect an error occurred by an operation of the calculation circuit 123. The second error detection circuit EDET2 may detect various types of errors such as invalid calculation (e.g., inner product of vectors with different dimensions or division by zero) and loss of significance.

The third error detection circuit EDET3 may collect the error record RCD from the input/output circuit 160. For example, the input/output circuit 160 may further include an error correction code (ECC) circuit 162. The ECC circuit 162 may detect damage (e.g., defect of integrity) of an operand read from the memory cell array 110, and may correct an error equal to or less than a predetermined number of bits. The third error detection circuit EDET3 may collect an error record RCD indicating a correctable error occurrence for an operand stored in the memory cell array 110 or an error record RCD indicating an uncorrectable error occurrence for an operand stored in the memory cell array 110.

In an embodiment, the ECC circuit 162 may be implemented as an on-die ECC circuit. However, the scope of the present disclosure is not limited thereto.

The error detection circuits EDET may store the collected one or more error records RCD in the error record register 124.

FIG. 8 is a view exemplarily showing a type of the error record that may be stored in the error record register of FIG. 7. Referring to FIGS. 1 to 8, the error record register 124 may store some of first to eighth error records RCD1-RCD8.

The first to eighth error records RCD1-RCD8 may correspond to different error codes. For example, the first to eighth error records RCD1-RCD8 may each correspond to the error codes 0x01 to 0x08. The error record register 124 may store the error record RCD in a form of the error code.

The first to eighth error records RCD1-RCD8 may correspond to different types of errors. For example, the first error record RCD1 may indicate calculation result size overflow; the second error record RCD2 may indicate calculation result size underflow; the third error record RCD3 may indicate an undefined instruction (or an invalid instruction); the fourth error record RCD4 may indicate loss of significance; the fifth error record RCD5 may indicate damage of an operand stored in the operation register array; the sixth error record RCD6 may indicate invalid calculation; the seventh error record RCD7 may indicate that a correctable error occurs in an operand stored in the memory cell array 110; and the eighth error record RCD8 may indicate that an uncorrectable error occurs in an operand stored in the memory cell array 110. However, the scope of the present disclosure is not limited thereto. For example, the error record register 124 may further include another error record in addition to the first to eighth error records RCD1-RCD8.

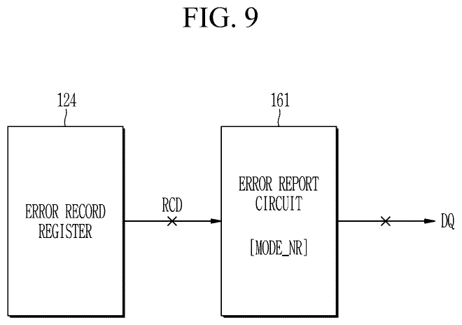

FIG. 9 is a drawing showing an operation of the error report circuit operating in the non-report mode. Referring to FIGS. 1 to 9, the error report circuit 161 may operate in the non-report mode MODE_NR based on the report level RPL. In the non-report mode MODE_NR, the error report circuit 161 may not output one or more error records RCD stored in the error record register 124 after the in-memory processing operation is completed. For example, if the report level RPL indicates the non-report mode MODE_NR, the control logic circuit 140 may control the processing management circuit 122 to block the one or more error records RCD from being read from the error record register 124. In the non-report mode MODE_NR, the error report circuit 161 may maintain the plurality of data pins in an inactive state.

In an embodiment, the embodiment in which the error record RCD is not read from the error record register 124 has been representatively described in FIG. 9, but the scope of the present disclosure is not limited thereto. For example, regardless of whether the report level RPL indicates a certain mode, the processing management circuit 122 may provide the one or more error records RCD from the error record register 124 to the error report circuit 161. For example, although the one or more error records RCD are sent to the error report circuit 161, the error report circuit 161 may maintain the plurality of data pins in an inactive state regardless of the received one or more error records RCD.

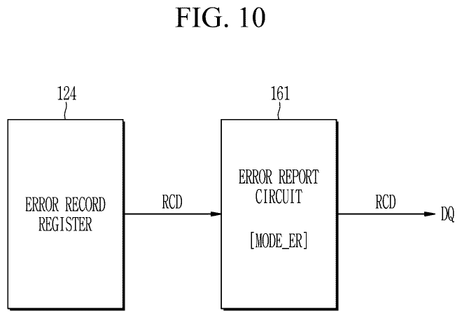

FIG. 10 is a drawing showing an operation of the error report circuit operating in the error report mode. Referring to FIGS. 1 to 10, the error report circuit 161 may operate in the error report mode MODE_ER based on the report level RPL. In the error report mode MODE_ER, the error report circuit 161 may output one or more error records RCD stored in the error record register 124 in a form of the data signals DQ after the in-memory processing operation is completed.

In an embodiment, the error report circuit 161 may output all error records RCD stored in the error record register 124 as the data signal DQ. However, the scope of the present disclosure is not limited thereto, and the error report circuit 161 may output only some of the error records RCD stored in the error record register 124 as the data signal DQ.

In an embodiment, the error report circuit 161 may operate in two or more types of error report modes MODE_ER based on the report level RPL. For example, the error report circuit 161 may output only some of the error records RCD stored in the error record register 124 as the data signal DQ based on the report level RPL, or may output all error records RCD stored in the error record register 124 as the data signal DQ. A method in which the error report circuit 161 operates in two or more types of error report modes MODE_ER will be described in more detail below with reference to FIGS. 12 to 14.

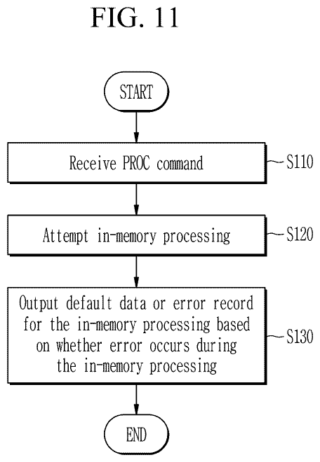

FIG. 11 is a flowchart showing the operation of the memory device operating in the error report mode. Referring to FIGS. 1 to 11, in an operation S110, the memory device 100 may receive the processing command PROC. For example, the report level RPL indicating the error report mode MODE_ER may be stored in the report level register 124, and the memory device 100 may receive the command/address signals C/A indicating the processing command PROC.

In an operation S120, the memory device 100 may attempt the in-memory processing. For example, the in-memory processor 120 may attempt to perform the in-memory processing operation corresponding to the instruction identifier ID_INST included in the processing command PROC. If an error is detected during the in-memory processing operation, the error detection circuit EDET may store the error record corresponding to the detected error in the error record register 124.

In an operation S130, the memory device 100 may output default data DFD or the error record RCD for the in-memory processing, based on whether the error occurs during the in-memory processing. For example, if the error occurs during the in-memory processing, the error report circuit 161 may output one or more error records RCD stored in the error record register 124 in a form of the data signals DQ to the host device 10. If the error does not occur during the in-memory processing, the error report circuit 161 may output the default data DFD in a form of the data signals DQ to the host device 10.

In an embodiment, the report level RPL indicating the error non-report mode MODE_NR may be stored in the report level register 124. According to the report level RPL indicating the error non-report mode MODE_NR, the memory device 100 may operate in the error non-report mode MODE_NR. For example, the memory device 100 may perform only the steps S110 and S120 described above, and may not perform the operation S130.

FIG. 12 is a drawing showing the report level register of FIG. 2 implemented according to an embodiment. Referring to FIGS. 1 to 6 and 12, the report level register 141 of FIG. 3 may be implemented as a report level register 241 below. Hereinafter, a difference between the report level register 141 and the report level register 241 will be mainly described.

An operation code OP of the report level register 241 may indicate a report level RPL. The report level RPL may indicate one of the non-report mode MODE_NR, all error report modes MODE_ER_ALL, and an important error report mode MODE_ER_IMP. For example, the report level register 241 may indicate the non-report mode MODE_NR if the operation code OP of the report level register 241 is “0x00”, the report level register 241 may indicate the all error report modes MODE_ER_ALL if the operation code OP of the report level register 241 is “0x01”, and the report level register 241 may indicate the important error report mode MODE_ER_IMP if the operation code OP of the report level register 241 is “0x02”. However, the scope of the present disclosure is not limited to a value of the operation code OP of the report level register 241.

An operation mode of the memory device 100 may be determined based on the report level RPL.

In an embodiment, if the report level RPL indicates the non-report mode MODE_NR, the memory device 100 may not provide the error record RCD to the host device 10 as an operation sequence in response to the processing command PROC, similar to the one described above with reference to FIG. 5.

In an embodiment, if the report level RPL indicates the all error report modes MODE_ER_ALL, the memory device 100 may provide all error records RCD stored in the error record register 124 to the host device 10 as the operation sequence in response to the processing command PROC, similar to the one described above with reference to FIG. 6. For example, the memory device 100 may output the all error records RCD stored in the error record register 124 in a form of the data signals DQ between the fourth time point t4 and the fifth time point t5 described above with reference to FIG. 6.

In an embodiment, if the report level RPL indicates the important error report mode MODE_ER_IMP, the memory device 100 may provide an important error record among the error records RCD stored in the error record register 124 to the host device 10 as the operation sequence in response to the processing command PROC, similar to the one described above with reference to FIG. 6. For example, the memory device 100 may output the important error records among the error records RCD stored in the error record register 124 as the data signals DQ between the fourth time point t4 and the fifth time point t5 described above with reference to FIG. 6.

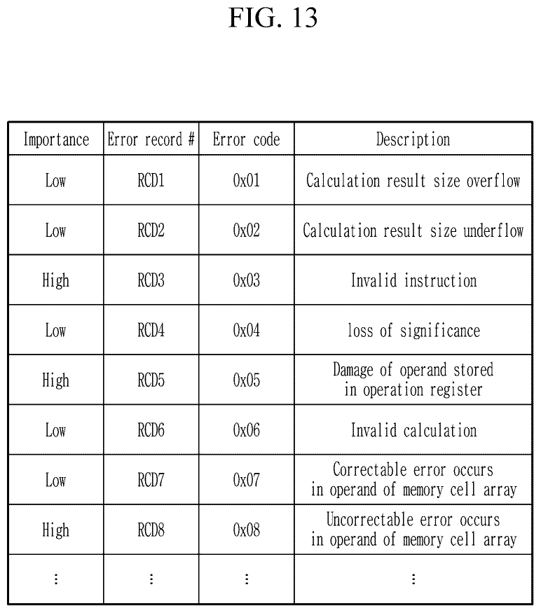

FIG. 13 is a view exemplarily showing an importance of each error record that may be stored in the error record register of FIG. 7.

Referring to FIGS. 1 to 8, FIG. 12, and FIG. 13, the memory device 100 may classify the importance of the error record RCD according to a cause of the error.

The processing management circuit 122 may classify an error having a high possibility of repeatedly occurring the same error according to an operation of the memory system MS as an error of high importance. For a more detailed example, the processing management circuit 122 may classify errors corresponding to the third, fifth, and eighth error records RCD3, RCD5, and RCD8 as errors of high importance.

The processing management circuit 122 may classify an error having a low possibility of repeatedly occurring the same error according to the operation of the memory system MS as an error of low importance. For example, the processing management circuit 122 may classify errors corresponding to the first, second, fourth, sixth, and seventh error records RCD1, RCD2, RCD4, RCD6, and RCD7 as errors of low importance.

Hereinafter, the error record corresponding to the error of high importance may be referred to as the high importance error record RCD_High. For example, the third, fifth, and eighth error records RCD3, RCD5, and RCD8 may be referred to as the high importance error record RCD_High. Similarly, the error record corresponding to the error of low importance may be referred to as the low importance error record RCD_Low. For example, the first, second, fourth, sixth, and seventh error records RCD1, RCD2, RCD4, RCD6, and RCD7 may be referred to as the low importance error record RCD_Low.

In an embodiment, the importance of the first to eighth error records RCD1 to RCD8 described above with reference to FIG. 8 may be set as described in FIG. 13, but the scope of the present disclosure is not limited thereto. For example, the processing management circuit 122 may classify the importance of some of the first to eighth error records RCD1 to RCD8 differently from the one shown in FIG. 13, and may classify an importance of an error record other than the first to eighth error records RCD1 to RCD8 in a similar manner.

In an embodiment, the processing management circuit 122 may classify the importance of each of the error records RCD stored in the error record register 124 into three or more levels. For example, the processing management circuit 122 may classify the importance of each of the error records RCD stored in the error record register 124 as “high”, “medium”, and “low”. For example, the scope of the present disclosure is not limited to a criterion by which the processing management circuit 122 classifies the importance of each of the error records RCD stored in the error record register 124.

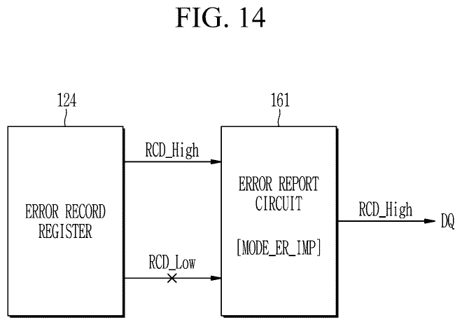

FIG. 14 is a drawing showing an operation of the error report circuit operating in the important error report mode. Referring to FIGS. 1 to 14, the error report circuit 161 may operate in the important error report mode MODE_ER_IMP based on the report level RPL. In the important error report mode MODE_ER_IMP, the error report circuit 161 may output high importance error records RCD_High among the error records RCD stored in the error record register 124 as the data signals DQ after the in-memory processing operation is completed.

For a more detailed example, after the in-memory processing operation is completed, one or more low importance error records RCD_Low and one or more high importance error records RCD_High may be stored in the error record register 124. In the important error report mode MODE_ER_IMP, the error report circuit 161 may not read the low importance error records RCD_Low from the error record register 124, but may read only the high importance error records RCD_High from the error record register 124. The error report circuit 161 may also output the error records (i.e., the one or more high importance error records RCD_High) read from the error record register 124 as the data signals DQ.

In an embodiment, the low importance error records RCD_Low are not read from the error record register 124 as described in FIG. 14, but the scope of the present disclosure is not limited thereto. For example, regardless of whether the report level RPL indicates a certain mode, the processing management circuit 122 may provide both the low importance error records RCD_Low and the high importance error records RCD_High to the error report circuit 161. Although both the low importance error records RCD_Low and the high importance error records RCD_High are sent to the error report circuit 161, the error report circuit 161 may filter out only the high importance error records RCD_High as the data signals DQ in the important error report mode MODE_ER_IMP.

In an embodiment, if the error report circuit 161 operates in the all error report modes MODE_ER_ALL, the error report circuit 161 may output all error records RCD stored in the error record register 124 as the data signals DQ, similar to the one described above with reference to FIG. 10.

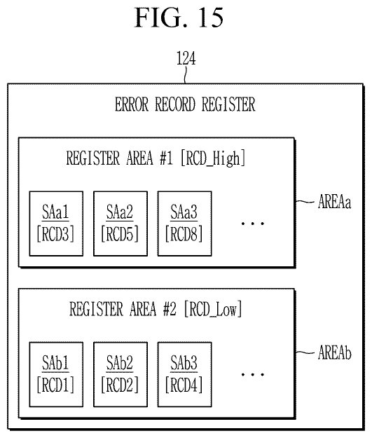

FIG. 15 is a block diagram showing the error record register of FIG. 14 implemented according to an embodiment. Referring to FIGS. 1 to 15, the error record register 124 may include a first register area AREAa and a second register area AREAb.

The first register area AREAa may store the high importance error records RCD_High. The second register area AREAb may store the low importance error records RCD_Low. Therefore, if the memory device 100 operates in the important error report mode MODE_ER_IMP, the error report circuit 161 may not read the second register area AREAb, but may read only the first register area AREAa.

Each of the first register area AREAa and the second register area AREAb may include a plurality of sub-areas SA.

The first register area AREAa may include a plurality of sub-areas SAa. For example, the first register area AREAa may include the sub-areas SAa1, SAa2, and SAa3.

Each of the plurality of sub-areas SAa may store the high importance error record RCD_High corresponding to different type each other. For example, the sub-areas SAa1, SAa2, and SAa3 may respectively store the third error record RCD3, the fifth error record RCD5, and the eighth error record RCD8.

The second register area AREAb may include a plurality of sub-areas SAb. For example, the second register area AREAb may include the sub-areas SAb1, SAb2, and SAb3.

Each of the plurality of sub-areas SAb may store the low importance error record RCD_Low corresponding to different type each other. For example, the sub-areas SAb1, SAb2, and SAb3 may respectively store the first error record RCD1, the second error record RCD2, and the fourth error record RCD4.

For example, the error detection circuit EDET may store the error record RCD in the sub-area SA predetermined according to a type of the error record RCD. For example, each of the plurality of sub-areas SA represents a different type of the error record RCD, and thus an error code of each error record RCD may not include information on which type of the error that the error record RCD corresponds to. Therefore, according to the embodiment of FIG. 15, a capacity of the error record RCD stored in each of the plurality of sub-areas SA may be minimized, and the memory device 100 may be implemented with the error record register 124 having a smaller capacity.

In an embodiment, if the error code of each error record RCD is implemented so as not to indicate the error type, the error report circuit 161 may generate the error record RCD to be provided to the host device 10 by adding one or more bits indicating the error type corresponding to the sub-area SA from which the error record RCD is read to the error record RCD read from the error record register 124. However, the scope of the present disclosure is not limited thereto.

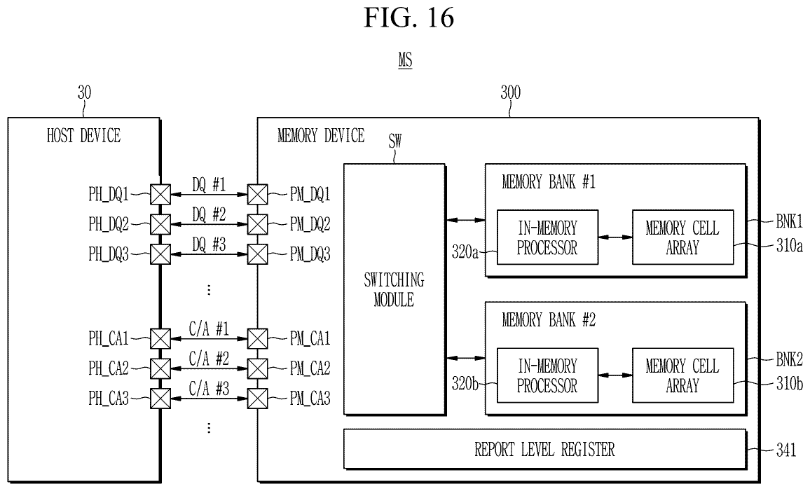

FIG. 16 is a block diagram showing a memory system according to an embodiment. Referring to FIGS. 1 to 16, the memory system MS may include a memory controller 30 and a memory device 300.

The memory device 300 may include a plurality of memory banks BNK. For example, the memory device 300 may include a first memory bank BNK1 and a second memory bank BNK2.

Each of the first memory bank BNK1 and the second memory bank BNK2 may include an in-memory processor 320 and a memory cell array 310. For example, the first memory bank BNK1 may include a first memory cell array 310a and a first in-memory processor 320a, and the second memory bank BNK2 may include a second memory cell array 310b and a second in-memory processor 320b.

In an embodiment, the first memory cell array 310a and the first in-memory processor 320a may respectively correspond to the memory cell array 110 and the in-memory processor 120 described above with reference to FIGS. 1 to 11.

The first in-memory processor 320a and the second in-memory processor 320b may operate independently of each other. For example, the first in-memory processor 320a may perform a calculation operation based on an operand provided from the first memory cell array 310a. The second in-memory processor 320b may perform a calculation operation based on an operand provided from the second memory cell array 310b.

A host device 30 may include a plurality of data pins PH_DQ and a plurality of command/address pins PH_CA.

The memory device 300 may include a plurality of data pins PM_DQ and a plurality of command/address pins PM_CA.

The plurality of command/address pins PH_CA may be respectively connected to the plurality of command/address pins PM_CA through different channels.

The host device 30 may provide a plurality of command/address signals C/A to the memory device 300 via channels connected to the plurality of command/address pins PH_CA. For example, the host device 30 may provide the first command/address signal C/A #1 to the first command/address pin PM_CA1 via the first command/address pin PH_CA1; may provide the second command/address signal C/A #2 to the second command/address pin PM_CA2 via the second command/address pin PH_CA2; and may provide the third command/address signal C/A #3 to the third command/address pin PM_CA3 via the third command/address pin PH_CA3. In an embodiment, three command/address signal channels are used as shown in FIG. 16, but the scope of the present disclosure is not limited thereto. For example, each of the host device 30 and the memory device 300 may include 7 or 14 command/address pins.

The plurality of data pins PH_DQ may be respectively connected to the plurality of data pins PM_DQ through different channels.

Through channels connected to the plurality of data pins PH_DQ, the host device 30 may provide a plurality of data signals DQ to the memory device 300, or may receive a plurality of data signals DQ from the memory device 300. For example, the host device 30 may provide the first data signal DQ #1 to the first data pin PM_DQ1 via the first data pin PH_DQ1; may provide the second data signal DQ #2 to the second data pin PM_DQ2 via the second data pin PH_DQ2; and may provide the third data signal DQ #3 to the third data pin PM_DQ3 via the third data pin PH_DQ3. The data signal DQ may carry (or transmit) various types of data DATA such as an error record RCD and default data DFD described above with reference to FIGS. 1 to 11. In an embodiment, three data channels are used as shown in FIG. 16, but the scope of the present disclosure is not limited thereto. For example, each of the host device 30 and the memory device 300 may include 8, 16, or 32 data pins.

The first memory bank BNK1 and the second memory bank BNK2 may share the plurality of data pins PM_DQ. For example, the memory device 300 may include a switching module SW. The switching module SW may connect one of the first memory bank BNK1 and the second memory bank BNK2 to the plurality of data pins PM_DQ.

The host device 30 may collectively control a plurality of in-memory processors 320 based on a plurality of command/address signals C/A. For example, the host device 30 may simultaneously provide a processing command PROC to the first memory bank BNK1 and the second memory bank BNK2 based on the plurality of command/address signals C/A. The first in-memory processor 320a and the second in-memory processor 320b may simultaneously perform an in-memory processing operation in response to the processing command PROC.

Each of the first in-memory processor 320a and the second in-memory processor 320b may simultaneously generate one or more error records RCD corresponding to the processing command PROC. For example, as the host device 10 issues one processing command PROC, the error record RCD may be generated in both the first in-memory processor 320a and the second in-memory processor 320b. For example, if an instruction corresponding to the instruction identifier ID_INST included in the processing command PROC is not stored in the first in-memory processor 320a and the second in-memory processor 320b, each of the first in-memory processor 320a and the second in-memory processor 320b may generate the error record RCD.

In an embodiment, the error report circuit 161 described above with reference to FIGS. 1 to 11 may be included in each of the first memory bank BNK1 and the second memory bank BNK2. In an embodiment, the switching module SW may provide the error record RCD provided from the error report circuit 161 of each of the first memory bank BNK1 and the second memory bank BNK2 to the host device 30 through the plurality of data pins PM_DQ. However, the scope of the present disclosure is not limited thereto.

In an embodiment, the error report circuit 161 described above with reference to FIGS. 1 to 15 may be included in the switching module SW. For example, the first memory bank BNK1 and the second memory bank BNK2 may share the error report circuit 161. In this case, the error report circuit 161 may provide a merged result of one or more error records RCD received from each of the first in-memory processor 320a and the second in-memory processor 320b to the host device 30 through the plurality of data pins PM_DQ. For example, the error reporting circuit 161 may provide a pair of error records with same type, which are respectively provided from the first in-memory processor 320a and the second in-memory processor 320b, as one error record to the host device 10, thereby reducing an amount of data provided to the host device 30 through the plurality of data pins PM_DQ. However, the scope of the present disclosure is not limited thereto.

In an embodiment, the first memory bank BNK1 and the second memory bank BNK2 may share a report level register 341.

The contents described above are specific embodiments for implementing the present disclosure. The present disclosure may include not only the above-described embodiments but also embodiments that may be simply changed in design or may be easily modified. Additionally, the present disclosure may also include technologies that may be easily modified and implemented using the embodiments. Therefore, the scope of the present disclosure should not be limited to the above-described embodiments, but should be defined by the claims described below as well as the claims and equivalents of the present disclosure.

What is claimed is:

1. A memory device comprising:
an in-memory processor configured to receive a processing command from an external host device and perform an in-memory processing operation in response to the processing command; and
an error report circuit configured to provide, in response to the processing command, one or more error records indicating errors detected during the in-memory processing operation, to the external host device.

2. The memory device of claim 1, further comprising:
one or more data pins,
wherein the error report circuit is configured to provide the one or more error records to the external host device by the one or more data pins.

3. The memory device of claim 1,
wherein the in-memory processor is configured to perform the in-memory processing operation between a first time point and a second time point, and
wherein the error report circuit is configured to provide the one or more error records to the external host device at a third time point after a report preparation time elapses from the second time point.

4. The memory device of claim 1, further comprising:
a memory cell array storing a first operand for the in-memory processing operation,
wherein the in-memory processor comprises:
an operation register array configured to store a second operand for the in-memory processing operation;
a calculation circuit configured to generate a calculation result based on at least one of the first operand and the second operand;
an error detection circuit configured to generate the one or more error records; and
an error record register configured to store the one or more error records provided from the error detection circuit.

5. The memory device of claim 4,
wherein the error detection circuit includes:
a first error detection circuit configured to collect error records corresponding to an integrity of the second operand and a size of the calculation result, from the operation register array.

6. The memory device of claim 4,
wherein the error detection circuit includes:
a second error detection circuit configured to collect error records corresponding to generation of the calculation result, from the calculation circuit.

7. The memory device of claim 4, further comprising:
an error correction code circuit connected to the memory cell array,
wherein the error detection circuit includes:
a third error detection circuit configured to collect error records corresponding to an integrity of the first operand, from the error correction code circuit for the memory cell array.

8. The memory device of claim 4, further comprising:
a report level register configured to determine an operation mode of the error report circuit,
wherein the operation mode of the error report circuit includes a first error report mode, a second error report mode,
wherein the error report circuit is configured to provide all error records stored in the error record register to the external host device in response to the first error report mode, and
wherein the error report circuit is configured to provide some of the error records stored in the error record register to the external host device in response to the second error report mode.

9. A memory device comprising:
a plurality of data pins;
a report level register configured to store a report level;
an in-memory processor configured to perform an in-memory processing operation in response to a processing command and generate one or more error records indicating information of an error occurring during the in-memory processing operation; and
an error report circuit configured to provide, based on the report level, the one or more error records of the in-memory processing operation to the plurality of data pins.

10. The memory device of claim 9, wherein:
the in-memory processor is configured to perform the in-memory processing operation during a first time period;
the error report circuit is configured to maintain the plurality of data pins in an inactive state during the first time period; and
the error report circuit is configured further to output, in response to the report level indicating an error report mode, the one or more error records to the plurality of data pins during a second time period after the first time period.

11. The memory device of claim 10,
wherein the error report circuit is configured further to maintain, in response to the report level indicating a non-report mode, the plurality of data pins in the inactive state during the second time period.

12. The memory device of claim 10,
wherein a start point of the second time period is a time point at which a report preparation time elapses from an end point of the first time period.

13. The memory device of claim 9,
wherein the report level register is configured to store the report level in response to a mode register write command, and
wherein the report level indicates an error report mode or a non-report mode.

14. The memory device of claim 9, further comprising:
a memory cell array storing a first operand used for the in-memory processing operation,
wherein the in-memory processor comprises:
an operation register array configured to store a second operand used for the in-memory processing operation;
a calculation circuit configured to generate a calculation result based on at least one of the first operand and the second operand during a first time period;
an error detection circuit configured to generate the one or more error records; and
an error record register configured to store the one or more error records.

15. The memory device of claim 14,
wherein the report level indicates an error report mode or a non-report mode,
wherein the error report mode includes a first error report mode and a second error report mode,
wherein the error record register is configured to store the one or more error records as one of a first type error record and a second type error record, and
wherein the error report circuit is configured to provide, in response to the report level indicating the first error report mode or the second error report mode, the first type error record to the plurality of data pins.

16. The memory device of claim 15,
wherein the error report circuit is configured further to provide, in response to the report level indicating the second error report mode, the second type error record to the plurality of data pins.

17. The memory device of claim 15,
wherein the error record register includes a first register area configured to store the first type error record and a second register area configured to store the second type error record, and
wherein the first type error record and the second type error record represent different error causes of the error occurring during the in-memory processing operation.

18. The memory device of claim 17,
wherein each of the different error causes is one of a damage of the first operand, a damage of the second operand, a size overflow of the calculation result, a size underflow of the calculation result, an undefined calculation request, an undefined instruction, and loss of significance.

19. An operation method of a memory device including an in-memory processor, the operation method comprising:
receiving a processing command;
attempting in-memory processing corresponding to the processing command; and
outputting one of default data and an error record for the in-memory processing, based on whether an error occurs during the in-memory processing,
wherein the default data represent that the in-memory processing has no error.

20. The memory device of claim 19,
wherein the outputting is performed after a predetermined length of time elapses after the processing command is received.
